(19) United States
(12) Patent Application Publication
(10) Pub. No.: US 2026/0213493 A1
(43) Pub. Date: Jul. 23, 2026

(54) COLLOIDAL BULK NANOCRYSTAL LASER AND RELATED METHOD

(71) Applicants: UNIVERSITEIT GENT, Gent (BE); IMEC VZW, Leuven (BE)

(72) Inventors: Pieter GEIREGAT, Gent (BE); Zeger HENS, Gent (BE); Dries VAN THOURHOUT, Gent (BE); Ivo TANGHE, Gent (BE)

(21) Appl. No.: 19/142,350

(22) PCT Filed: Dec. 15, 2023
(86) PCT No.: PCT/EP2023/086175

§ 371 Date: Jun. 23, 2025

(30) Foreign Application Priority Data
Dec. 23, 2022 (EP) 22216433.7

(51) Int. Cl. H01S 5/10

(52) U.S. Cl. CPC H01S 5/1067

(57) ABSTRACT

A method of manufacturing an optically-pumped or electrically-pumped device with feedback structure includes the steps of: providing a substrate; providing at least one optical confinement layer on top of the substrate and including one or more integrated optical structures; forming a colloidal dispersion comprising bulk semiconductor nanocrystals and/or bulk hetero nanocrystals, with bulk semiconductor nanocrystals being defined as semiconductor nanocrystals having linear optical properties as determined by the corresponding material composition; providing the colloidal dispersion, thereby forming a semiconductor film and forming the device. An optically-pumped or electrically-pumped device with feedback structure includes a substrate, at least one optical confinement layer, and at least one semiconductor film.

### TECHNICAL FIELD

The present invention generally relates, amongst others, to a method of manufacturing an optoelectronic device and to the related optoelectronic device. The present invention relates more particularly to a method of manufacturing an optoelectronic device from a colloidal dispersion comprising bulk semiconductor nanocrystals or bulk hetero nanocrystals comprising bulk semiconductor nanocrystals for achieving light amplification and lasing through stimulated emission.

### BACKGROUND

The fabrication of optoelectronic materials, components and devices by solution-based processing has been an ongoing research and development effort. For example, semiconducting polymers have been used to fabricate organic photovoltaic cells or organic light emitting diodes. To circumvent stability issues of organic materials, and to extend functionality from visible to infrared wavelengths, solution-processable inorganic materials or inorganic/organic hybrids have been introduced as alternatives. Examples of such alternatives comprise lead halide perovskites, or LHP, thin films, colloidal quantum dots, quantum rods or nanoplatelets of a variety of semiconductors, such as III-V, II-VI, IV-VI, and more recently, nanocrystals of LHP compounds, which were all studied for example for solar energy conversion, light detection or light emission applications. US2019/0280153A1, US2020/0332186A1, the scientific publication by Wang et al. entitled “Quaternary Alloy Quantum Dots: Toward Low-Threshold Stimulated Emission and All-Solution-Processed Lasers in the Green Region” published in Advanced Optical Materials 2015, 3, 652-657, the scientific publication by Beard et al. entitled “Multiple Exciton Generation in Colloidal Silicon Nanocrystals” published in Nano Letters 2007, Vol. 7, No. 8, 2506-2512, and US2001/0046244A1 describe light-emitting structures and devices comprising semiconductor nanocrystals, mostly quantum dots demonstrating a core/shell structure, which are capable of emitting light upon excitation and which show strong quantum confinement effects. US2004/0017834A1 describes narrow fluorescence from a chromophore embedded within a plurality of dielectric layers that serve to lower the optical density of states. Devices such as light emitting displays and lasers in US2004/0017834 are based on the combination of multiple core-dielectric layer structures, and, in the latter case, an additional optical cavity that provides the necessary optical feedback. The core in US2004/0017834 can include at least on chromophore, which can include a semiconducting nanoparticle. It is needed in US2004/0017834 to completely surround the core with the dielectric layers. This is essential in US2004/0017834 to create an atomic density of states for the photons.

Among the different light emitting devices, lasers stand out because they provide monochromatic, coherent and directional light. Hence, the development of lasers based on solution-processed gain materials has been a continuous effort within the field of solution-processed optoelectronics. Stimulated emission by the different classes of solution-processed gain materials can be characterized by the lifetime of the inverted state, the material gain and the pump threshold needed to obtain stimulated emission or lasing. So far, however, the different classes of solution-processed gain materials fall short on these metrics. Market-ready devices that can be used for example for projection, display, sensing or communication purposes have yet to be demonstrated.

### SUMMARY

Colloidal quantum dots, also referred to as QDs, are semiconductor nanocrystals subject to strong confinement in one or more of the three independent spatial directions. While sometimes arbitrarily set at 10 nm, an upper diameter for the QDs characterizing this regime of strong confinement is material dependent and often associated with the exciton Bohr radius of the corresponding bulk semiconductor. A better approach is to obtain this diameter from the variation of the bandgap with nanocrystal size using a generic expression or ‘sizing curve’, in which the diameter discerning weak from strong confinement is the sole adjustable parameter. Upper limits for CdS, CdSe and CsPbBr₃ amount to 3.9 nm, 5.9 nm and 6.1 nm, respectively. In the case of colloidal quantum rods, strong confinement is limited to two independent spatial directions, while for colloidal nanoplatelets, strong confinement is only attained along a single spatial direction.

A significant advantage of QDs as a gain material is the considerable material gain—easily exceeding 1000 cm⁻¹—and the straightforward adaptation of the emission wavelength through the QD size. As a result, QD lasers can be micron-sized and operate across a broad spectral range from the blue to the near infrared.

A further advantage of QDs is their suitability for solution-based processing by means of wet deposition techniques, such as, but not limited to, bar coating, spin coating, spray coating and inkjet printing. As a result, QDs can be combined with a broad range of laser cavity designs, without imposing constraints related to, for example but not limited to, lattice mismatch with a substrate and a large thermal budget. Finally, QDs can be processed into densely packed films with high loading fraction of active semiconductor material, thereby opposing approaches using epitaxially grown QDs or solid state glassy-matrix approaches.

However, excited colloidal QDs can show net stimulated emission only when holding two or more electron-hole pairs or excitons per QD. Given the typical Auger recombination rate of bi- and multi excitons—1-100 ns⁻¹—QDs have an inverted state lifetime of 10-1000 ps. Therefore, QD lasing is typically only achieved using femtosecond optical pumping, not through continuous wave optical or direct current electrical pumping.

Several directions have been followed to extend the inverted-state lifetime. A first example involves Type 2 core/shell QDs, with a blue-shifted biexciton emission. This approach involves the formation of spatially separated electron-hole pairs, that can show optical gain from a population of single excitons. However, even though the formed inverted state is characterized by a longer inverted state lifetime, the spatial separation of the electron-hole leads to a strong reduction of the material gain. No operating laser has been demonstrated using this approach.

A second example includes the formation of Type 1 core/shell QDs with an alloyed interface. It was shown that CdSe/CdS core/shell quantum dots with an alloyed interface exhibited a considerable reduction of the Auger recombination rate; down to 1 ns⁻¹ or less. While supported by theoretical considerations, this point has not been extended to different material systems until now. Even so, CdSe/CdS core/shell QDs were used to demonstrate QD lasers under nanosecond and quasi-CW optical pumping. However, the dilution of the emissive CdSe core in the CdS shell reduces the material gain, in particular when thick CdS shells are grown. Moreover, the system shows limited wavelength tunability with typical lasers operating in the range 620-650 nm.

A third example includes colloidal dot-in-rod heteronanocrystals. This structure was used to create self-assembled cavities. Lasing threshold is high and the advantage over CdSe/CdS core/shell QD remains unclear.

A fourth example includes colloidal nanoplatelets, also known as NPLs. As compared to GD QDs, 2D NPLs show a remarkably high material gain, and various optically pumped lasers using colloidal NPLs have been demonstrated. However, charge carrier recombination in NPLs is fast, giving typical exciton loss rates of 10 ns⁻¹. This reduces the inverted state lifetime and the threshold to attain lasing by electrical or continuous wave optical pumping complicated.

It is thus an object of embodiments of the present invention to propose an optically-pumped or electrically-pumped device with feedback structure, also referred to as an optoelectronic device, and a method of manufacturing thereof which preserves the advantages of colloidal QDs with respect to optical gain characteristics and ease-of-processing, but does not show the inherent shortcomings of the prior art. More specifically, it is an object of embodiments of the present invention to propose a method of manufacturing an optoelectronic device which demonstrates amplification and stimulated emission.

The scope of protection sought for various embodiments of the invention is set out by the independent claims.

The embodiments and features described in this specification that do not fall within the scope of the independent claims, if any, are to be interpreted as examples useful for understanding various embodiments of the invention.

There is a need in the field of semiconductor lasers for gain materials featuring an extended inverted-state lifetime without loss of material gain, thereby achieving light emission and amplification. More particularly, there is a need for a method of manufacturing an optoelectronic device and for the obtained optoelectronic device which provides broadband amplified spontaneous emission and lasing.

This object is achieved, according to a first example aspect of the present disclosure, by a method of manufacturing an optically-pumped or electrically-pumped device with feedback structure, also referred to as an optoelectronic device, the method comprising the steps of:
providing a substrate;
providing at least one optical confinement layer on top of the substrate, wherein one or more of the optical confinement layers comprise one or more integrated optical feedback structures;
forming a colloidal dispersion comprising bulk semiconductor nanocrystals and/or bulk hetero nanocrystals, whereby a bulk hetero nanocrystal comprises at least two parts, with at least one part comprising a bulk semiconductor nanocrystal, whereby bulk semiconductor nanocrystals have a size in three independent directions larger than larger an upper limit for strong quantization of the corresponding bulk material, and with bulk semiconductor nanocrystals being defined as nanocrystals having linear optical properties as determined by the corresponding bulk material composition, and not as determined by a size or diameter of the semiconductor nanocrystals because the semiconductor nanocrystals are not in a regime of quantum confinement and so demonstrate linear optical properties as determined by the corresponding bulk materials, wherein the linear optical properties comprise absorption spectra and photoluminescence spectra, wherein the bulk semiconductor nanocrystals comprise:
   one or more II-VI semiconductor materials or alloys thereof;
   one or more III-V semiconductor materials or alloys thereof;
   one or more IV-VI semiconductor materials or alloys thereof;
   one or more Group IV semiconductor materials or alloys thereof;
   one or more Group I-III-VI₂ semiconductor materials or alloys thereof; or
   any combinations thereof; and
providing the colloidal dispersion:
   on top of one or more of the optical confinement layers, or
   embedded within one of the optical confinement layers, or
   between at least two of the optical confinement layers, or
   between the substrate and at least one of the optical confinement layers, thereby forming a semiconductor film from the colloidal dispersion, wherein the one or more optical confinement layers are configured to confine one or more optical modes in the semiconductor film and to add an optical feedback function to the one or more optical modes, and thereby forming the optically-pumped or electrically-pumped device with the optical integrated feedback structures.

In the context of the present disclosure, bulk semiconductor nanocrystals also referred as bulk three-dimensional or bulk 3D semiconductor nanocrystals are nanocrystals exhibiting linear optical properties determined by the material composition and not determined by their nanocrystal size/diameter/shape. Examples of linear optical properties include the optical constants and the photoluminescence spectrum related to the band-gap transition. Bulk semiconductor nanocrystals differ from semiconductor nanocrystals conveniently referred to as GD quantum dots, 1D quantum rods or 2D quantum wells or nanoplatelets, which have sizes in 3, 2 and 1 independent directions smaller than the upper limit do for strong quantization. Literature typically relates this upper limit for strong quantization to the exciton Bohr diameter, calculated according to the relation (a).

In the pursuit of optimal semiconductor gain materials, a historical and by now ‘text-book’ shift away from bulk systems has been evident. The community favored strongly confined systems, such as GD quantum dot or, very prominently, 2D quantum well structures. These systems promised advantages like improved spectral tunability, lower lasing thresholds, reduced temperature sensitivity, and higher switching speed. This while combatting downsides in bulk like higher temperature sensitivity, and carrier loss through diffusion. The practicality of epitaxial growth, despite its complexities, made these confined structures the dominant choice in laser technology.

However, this historical preference for confinement raises questions about the limitations and challenges that accompanied it. The epitaxial growth process presented difficulties in matching various requirements such as the lattice parameter of consecutive layers, leading to issues like the notorious ‘green gap’ in laser technology. Spectral tunability through shape/dimensionality control, while touted as a benefit, turned out to be practically limited—mainly due to the strain argument accompanying lattice matching. Threshold currents in epitaxial GD laser systems might be slightly lower, but modal gains are equally diminished due to sparse surface density of emitters. Temperature insensitivity, another supposed advantage, is only modestly achieved, given the strong dependence of the differential gain on temperature and high escape rates in shallow energetic barrier hetero-structures.

Bulk colloidal nanocrystals (BNCs) give new perspectives to the assumptions that led to the move away from bulk materials. Contrary to the limitations of epitaxial growth, BNC materials showcase disruptively high gain coefficients over a continuous spectral band. The BNC advantage lies in its ability to provide a high optical quality solution-processable ‘bulk’ system where carrier and optical confinement is achieved through for example an optional simple dielectric coating on top of the solution processed active BNC layer. This method avoids the difficulties of carrier and light confinement through epitaxial stacking, where strain matching dictates everything, while offering benefits like high electronic Density of States, a continuous spectral band, low non-radiative rates, reduced non-radiative surface recombination and absence of carrier diffusion. This is moreover combined with the possibility of a printable, cheap gain layer, contrasted to the expensive epitaxial growth of classical confined systems.

US2004/0017834A1 describes narrow fluorescence from a chromophore embedded within a plurality of dielectric layers that serve to lower the optical density of states. The QDs and the dielectric layers of US2004/0017834A1 make an inseparable unit. Devices such as light emitting displays and lasers in US2004/0017834 are based on the combination of multiple core-dielectric layer structures, and, in the latter case, an additional optical cavity that provides the necessary optical feedback. The dielectric layers introduced in US2004/0017834A1 serve to reduce the optical density of states which narrows the spontaneous emission by the chromophores, as described in paragraph [06] and claim 2 of US2004/0017834A1. In itself, this sequence of dielectric layers is insufficient to obtain optical feedback, for which an additional optical cavity is needed, cf. paragraph [09] and claim 28 of US2004/0017834A1. The optical cavity in US2004/0017834A1 narrows the optical density of state. This is clearly different from the present disclosure describing a film of bulk nanocrystals in combination with an optical cavity.

While US2004/0017834A1 describes narrow fluorescence from a chromophore embedded within a plurality of dielectric layers, the present disclosure is about amplified spontaneous and/or net stimulated emission from an ensemble of bulk nanocrystals processed as a dense thin film. US2004/0017834A1 involves an approach to form fluorescent emitting materials with narrow linewidth, mostly by the embedding of single emitters in a primary microcavity that serves to narrow the optical density of states. The core of US2004/0017834A1 can include at least on chromophore, which can include a semiconducting nanoparticle. It is needed in US2004/0017834 to surround the core with the dielectric layers. This is essential to create the photon atom states in US2004/0017834. Moreover, optical gain is only achieved by embedding the emitters and their primary cavity in a secondary cavity that provides optical feedback. With the present invention, there is no need to surround the at least one chromophore with dielectric layers. In other words, with the present disclosure, the dielectric layers do not have to surround the semiconductor nanocrystals.

In preferred embodiments the colloidal dispersion comprises bulk semiconductor nanocrystals, whereby bulk semiconductor nanocrystals are defined as nanocrystals having linear optical properties as determined by the corresponding material composition.

In other embodiments the colloidal dispersion comprises bulk hetero nanocrystals. A bulk hetero nanocrystal comprises at least two parts, with at least one part of these at least two parts comprising a bulk semiconductor nanocrystal. Preferably, the at least two parts of a bulk hetero nanocrystal have a different composition.

Bulk hetero nanocrystals comprise for example core/shell nanocrystals comprising at least one core and at least one shell surrounding the at least one core, whereby the at least one core or the at least one shell comprises a bulk semiconductor nanocrystal. Bulk hetero nanocrystals are for example obtained by coating a core (a semiconductor core, for example a bulk semiconductor nanocrystal) with one or more semiconductor shells.

In case the core of the bulk hetero nanocrystal comprises a bulk semiconductor nanocrystal, the core has linear optical properties as determined by the corresponding material composition. In case the shell or at least one of the shells comprises a bulk semiconductor nanocrystal, the shell or at least one of the shells has linear optical properties as determined by the corresponding material composition.

In particular embodiments both the core and the shell or shells may have linear optical properties as determined by the corresponding material composition of respectively the core and the shell or shells.

Preferably, the part of the bulk hetero nanocrystal having linear optical properties as determined by the corresponding material composition has the lowest band gap of all parts of the core/shell semiconductor bulk hetero nanocrystals and preferably a straddling band alignment with at least one other part of the core/shell bulk semiconductor bulk hetero nanocrystal.

With the method according to the present disclosure, net stimulated emission can be obtained from bulk semiconductor nanocrystals and/or bulk hetero nanocrystals comprising a bulk semiconductor nanocrystal. An exceptionally high material gain—up to 50000 cm¹—and long inverted state lifetime—up to 3 ns can be demonstrated in the optoelectronic device manufactured with the method according to the present disclosure. With the method according to the present disclosure, the bulk semiconductor nanocrystals and/or bulk hetero nanocrystals can be processed into semiconductor films to measure net modal gain and the bulk semiconductor nanocrystals and/or bulk hetero nanocrystals can be deposited on integrated optical structures such as for example 2D distributed feedback gratings. Lasing from such combined structures is achieved across for example a 50 nm wide wavelength range, set by the grating properties. Such bulk semiconductor nanocrystals therefore constitute a unique material to realize continuous wave optically pumped and electrically pumped solution-processed lasers. Further wavelength tuning is possible by changing the composition of the bulk semiconductor nanocrystals, either within the II-VI family or by using different semiconductor families, such as III-V or IV-VI or Group IV or Group I-III-VI₂ compounds. Compared to bulk films known in the art, for example bulk films comprising II-VI materials such as CdS, or another type of materials, the bottom-up approach of the method according to the present disclosure to realize the optoelectronic device enables bulk-like properties without the formation of typical bulk problems such as epitaxial strain, dislocations and other typical defects limiting the optical performance. Bulk films known in the art comprise for example continuous films of epitaxially connected solid crystal. Such bulk films are typically characterized by not having air void and/or inclusions of other materials.

In the context of the present disclosure, a semiconductor film comprising bulk colloidal semiconductor nanocrystals is formed from a colloidal dispersion using the solution processable method according to the present disclosure. The semiconductor film is continuous along the substrate. Each semiconductor nanocrystal demonstrates linear optical properties of the corresponding bulk semiconductor material of the nanocrystals. In other words, the semiconductor nanocrystals are not in a regime of confinement, hence demonstrating equivalent properties to a bulk material. In the context of the present disclosure, a thickness of the semiconductor film is comprised between 6 nm and 2 μm, for example between 6 nm and 1 μm. For example, a thickness of the semiconductor film is comprised between 50 nm and 100 nm, corresponding to 1 to 10 layers of bulk semiconductor nanocrystals in function of a size of the semiconductor nanocrystals. The semiconductor film is for example formed on top of one or more optical confinement layers which are formed on top of the substrate. Alternatively, the semiconductor film is for example formed on top of the substrate and between the substrate and at least one optical confinement layer. Alternatively, the semiconductor film is for example formed between at least two of the optical confinement layers. Alternatively, the semiconductor film is for example formed on top of the substrate so that the semiconductor film is embedded in one of the optical confinement layers. In this case, the optical confinement layer comprises at least a first optical confinement section formed on top of and in direct contact with the substrate and the optical confinement layer further comprises a second optical confinement section. The colloidal dispersion is provided between the first optical confinement section and the second optical confinement section, thereby forming the semiconductor film as embedded in the optical confinement layer. The first optical confinement section and the second optical confinement section can have different thicknesses. Alternatively, the first optical confinement section and the second optical confinement section have the same thickness.

In the context of the present disclosure, a colloidal dispersion is a system in which distributed semiconductor nanocrystals of one or more materials are dispersed in a continuous phase of another material, wherein the semiconductor nanocrystals demonstrate linear optical properties of corresponding bulk materials. The two phases may be in the same or different states of matter. In other words, a colloidal dispersion is understood as a mixture in which semiconductor nanocrystals of one substance are distributed throughout another substance. Dispersions do not display any structure, i.e., the particles dispersed in the liquid or solid matrix are assumed to be statistically distributed. A colloid is a heterogeneous mixture where the dispersed semiconductor nanocrystals have at least in one direction a dimension roughly between 1 nm and 1 μm or that in a system discontinuities are found at distances of that order.

In the context of the present invention, the substrate is for example a silicon substrate. The substrate may further optionally comprise a silicon oxide layer on top of the silicon. For example, the substrate comprises several micrometers of thermally grown silicon oxide formed on top of the silicon, for example 3 micrometers. Alternatively, the silicon substrate could be any suitable substrate. For example, the substrate could be a more thermally conductive substrate than silicon. For example, the substrate may comprise one or more of the following: silicon, silicon dioxide, silicon carbide, germanium, germanium-on-insulator, one or more III-V materials, silicon-on-insulator, lithium niobate, sapphire, generic integrated photonic platforms, generic integrated electronic platforms. Alternatively, the substrate could for example be a metallic or an optically non-transparent substrate since the inevitable high losses can be countered with the high gain coefficients demonstrated by the semiconductor film according to the present disclosure.

In the context of the present disclosure, a semiconductor film corresponds to a layer of the colloidal dispersion that is deposited onto the substrate or onto one or more of the optical confinement layers. For example, the semiconductor film is a microscopically thin film.

According to particular embodiments, the bulk semiconductor nanocrystals have a size in three independent directions larger than an upper limit d₀ for strong quantization, wherein d₀ corresponds to the exciton Bohr diameter of the corresponding bulk material calculated according to relation (a):

$${d}_{0} = 8 π \frac{{ε}_{∞} {ε}_{0} {ℏ}^{2}}{μ {m}_{0} {e}^{2}} \qquad ( a )$$

wherein ε₀ is the permittivity of the vacuum, h is Planck's constant, m₀ is the free electron mass, e the elementary charge, ε_{∞} is the high-frequency dielectric constant and μ is the reduced effective mass of the corresponding bulk material. Nanocrystals with one or more dimensions smaller than do are exposed to quantum confinement effects.

A size of a bulk semiconductor nanocrystal in the context of the present disclosure is for example a diameter or an edge length of the semiconductor nanocrystal.

As mentioned above, the bulk semiconductor nanocrystals have a size in three independent directions larger than 1d₀ for strong quantization. In preferred embodiments, the bulk semiconductor nanocrystals have a size in three independent directions larger than 1.2d₀ for strong quantization. Alternatively, the semiconductor nanocrystals have a size in three independent directions larger than 1.5d₀ for strong quantization. Alternatively, the semiconductor nanocrystals have a size in three independent directions larger than 2d₀ for strong quantization.

According to particular embodiments, the semiconductor nanocrystals have a size in three independent directions larger than an upper limit d₀ for strong quantization, wherein d₀ is obtained from fitting an experimental dependence of the semiconductor nanocrystals band gap E₁ on the size d of the semiconductor nanocrystals to a generic sizing curve according to relation (b):

$${E}_{1} ( d ) = \frac{1}{2} [ {E}_{0} + \sqrt{{E}_{0}^{2} + 8 \vert {E}_{0} \vert {απ}^{2} \frac{{R}_{y} {a}_{0}}{{ε}_{∞} {d}_{0}} {{e}^{- \frac{d}{{d}_{0}}} [ 1 - {e}^{- \frac{d}{{d}_{0}}} ]}^{- 2}} ] \qquad ( b )$$

wherein d₀ is the only adjustable parameter while E₀ is the band gap of the corresponding bulk material, α is a constant number equal to 0.7, R_{y} is the Rydberg energy of the corresponding bulk material, a₀ is the Bohr radius of the hydrogen atom, ε_{∞} is the high-frequency dielectric constant of the corresponding bulk material.

A size of a bulk semiconductor nanocrystal in the context of the present disclosure is for example a diameter, equivalent diameter or an edge length (for example the edge of a cube or the edge of a pyramid) of the bulk semiconductor nanocrystal.

Preferably, the semiconductor nanocrystals have a size in three independent directions larger than 1.2d₀ for strong quantization. Alternatively, the semiconductor nanocrystals have a size in three independent directions larger than 1.5d₀ for strong quantization. Alternatively, the semiconductor nanocrystals have a size in three independent directions larger than 2d₀ for strong quantization.

An upper limit to the useful bulk semiconductor nanocrystal's size could be defined as those sizes of the semiconductor nanocrystal for which the gain cross section σ_{g} becomes overshadowed by scattering from the nanocrystals themselves, an effect that can also be characterized by a scattering cross section σₛ, also in units of cm². Indeed, larger particles will scatter more light, leading to loss in the film, according to the Rayleigh scattering formula:

$${σ}_{s} = \frac{2 {π}^{5}}{3} \frac{{d}^{6}}{{λ}^{4}} {( \frac{{n}^{2} - 1}{{n}^{2} + 2} )}^{2} ∼ {V}^{2} \qquad ( 1 )$$

wherein n is the refractive index of the QDs, λ is the wavelength where the optical processes take place and d is a size of a semiconductor nanocrystal. Note that the scattering is defined here for a situation where the QDs are in vacuum, i.e. the refractive index of the environment is equal to 1. This results in a demand that only those semiconductor nanocrystals are to be considered where:

$${σ}_{g} > {σ}_{s} \qquad ( 2 )$$

As the gain cross section σ_{g}=gᵢ×V, i.e. ~V, with gᵢ the material gain and V the volume of the particle, one can rewrite the condition above as an upper limit of the size d. For example, if a refractive index n=3 is used, a wavelength of 500 nm and a cube-shaped particle with edge length d (V=d³), one will find that d<115 nm for the largest material gain we observed (50.000 cm⁻¹).

$$d < \sqrt[3]{{g}_{i} \frac{3 {λ}^{4}}{2 {π}^{5}} {( \frac{{n}^{2} + 2}{{n}^{2} - 1} )}^{2}} \qquad ( 3 )$$

Note that this relation holds only for semiconductor nanocrystals with a cubic shape, i.e., for which V=d³.

According to particular embodiments, forming the colloidal dispersion corresponds to forming the colloidal dispersion by reacting one or more solvent diluted precursors.

In the context of the present disclosure, a solvent diluted precursor comprises for example one or more of the following: metal-organic precursors, coordinated chalcogens, pnictides or mixtures thereof.

In the context of the present disclosure, a refractive index of the semiconductor film preferably ranges between 1.5 and 2.5 and is more preferably close to 1.6, for example between 1.5 and 1.7.

According to the scientific publication of Aubert et al., published in Nano Letters 2022, 22, pages 1778-1785, systematic determination of do, cf. relation (a), can be obtained by comparing the variation of the bandgap with nanocrystal size to a generic sizing function depending on do as the only adjustable parameter:

$${d}_{0} = 8 π \frac{{ε}_{∞} {ε}_{0} {ℏ}^{2}}{μ {m}_{0} {e}^{2}} \qquad ( a )$$

where ε_{∞} is the high-frequency dielectric constant of the material, ϑ₀=8.854·10⁻¹² is the vacuum permittivity, h=1.055.10⁻³⁴J·s is the reduced Planck constant, m₀=9.109·10⁻³¹ kg is the free electron mass, e=1.602·10⁻¹⁹ C is the proton charge, and μ is the reduced effective mass, which is calculated as:

$$\frac{1}{μ} = \frac{1}{{m}_{e}} + \frac{1}{{m}_{h}} ,$$

with mₑ and mₕ, the electron and hole effective masses, respectively, of the material of the semiconductor nanocrystal. According to this scientific publication, the upper limit d₀ of the strong quantization regime is as follows for a selected set of materials:

| | Upper limit of strong quantization, based on Bohr definition | | | | | | | | | |
|---|---|---|---|---|---|---|---|---|---|---|
| | CdS | CdSe | PbS | PbSe | CdTe | PbTe | InP | Si | HgTe | CsPbBr₃ |
| d₀ (nm) | 3.1 | 5.9 | 45 | 113 | 9.3 | 175 | 14.3 | 9.0 | 53 | 6.1 |
| | Upper limit of strong quantization, based on fitting. | | | | | | | | | |
| | CdS | CdSe | PbS | PbSe | CdTe | PbTe | InP | Si | HgTe | CsPbBr₃ |
| d₀ (nm) | 3.5 | 6.8 | 54 | 82 | 8.9 | 103 | 12.3 | 9.2 | 73 | 6.3 |

In the context of the present disclosure, a semiconductor nanocrystal can have one or more of the following compositions: CdS, CdSe, CdTe, CdSₓSe₁₋ₓ, wherein x is comprised between 0 and 1, CdSₓTe₁₋ₓ, CdSeₓTe₁₋ₓ, ZnS, ZnSe, ZnTe, ZnSₓSe₁₋ₓ, ZnSₓTe₁₋ₓ, ZnSeₓTe₁₋ₓ, all II-VI and their alloys, in arbitrary composition also including alkaline earth elements Mg, Ca, etc. and oxides such as ZnO; binary III-V semiconductors, ternary III-V semiconductors, nitrides, phosphides, arsenides, antimonides of aluminium, gallium indium, such as AlP, AlAs, InP, InAs, GaP, GaAs, in arbitrary composition and including their alloys; IV-VI semiconductors, such as PbS, PbSe, PbTe, PbSnS, PbSnSe in arbitrary composition and their alloys; group IV semiconductors, such as Si, Ge, Sn and their alloys, as well as all alloys of any combination of the previous materials and the combination of previous materials in core/shell and core/multi-shell systems.

Alternatively, a bulk semiconductor nanocrystal in the context of the present disclosure may be a Group II-VI compound, a Group II-V compound, a Group IV-VI compound, a Group III-V compound, a Group IV-VI compound, a Group I-III-VI compound, a Group II-IV-VI compound, a Group II-IV-V compound, such as for example ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, PbTe, or mixtures thereof.

According to particular embodiments, the bulk semiconductor nanocrystals are grown using a one-pot method by continuous injection of the solvent diluted precursors in the reaction chamber, preferably in the reaction volume.

This way, seeded growth is promoted through controlled addition of the solvent diluted precursors into the reaction chamber, preferably in the reaction volume, thereby achieving a low particle size dispersion for the colloidal dispersion. In other words, adding one or more solvent diluted precursors to the reaction chamber, preferably to the reaction volume corresponds to adding for example an equimolar solution of solvent diluted precursors to the reaction chamber, preferably to the reaction volume. For example, an equimolar precursor mixture, 0.5M, using a 2 mL/hour injection speed was found preferable for forming a colloidal dispersion according to the present disclosure.

According to particular embodiments, adding one or more solvent diluted precursors to the reaction chamber, preferably to the reaction volume, corresponds to adding the one or more solvent diluted precursors to the reaction chamber, preferably to the reaction volume, at a temperature comprised between 30° and 340° C.

A reaction temperature comprised for example between 30° and 340° C. in the reaction chamber ensures the growth of wurtzite cores and with minor zinc blend defects. The core growth of a semiconductor nanocrystal is for example tracked by taking aliquots during growth and measuring the relative position of a photoluminescence or absorption peak. The size of a semiconductor nanocrystal is later confirmed through for example transmission electron microscopy. A shell growth then immediately follows without in between purification by exchanging the injection mixture accordingly. This ensures that the interface remains unexposed to ambient conditions and promotes interfacial alloying which maintains a higher degree of passivation. After the synthesis, a purification cycle using for example a 3:1 mixture of isopropyl alcohol and methanol cleans the semiconductor nanocrystals from leftover organics sufficiently enough for later fabrication of the semiconductor film, while maintaining colloidal stability and luminescence efficiency.

According to particular embodiments, forming a colloidal dispersion comprising semiconductor nanocrystals corresponds to hot injection or a slow injection.

The synthesis of the colloidal dispersion uses a protocol of slow injection starting from so-called seeds. This implies that the synthesis of the colloidal dispersion starts in a reaction chamber from already pre-formed semiconductor nanocrystals and that solvent diluted precursors are slowly added to the reaction chamber to grow the semiconductor nanocrystals further. The solvent diluted precursors are for example Cd, S, Se, metalorganics, etc. This synthesis differs from what is known as ‘hot injection’ synthesis where all the solution diluted precursors are added from the start to the reaction chamber.

According to particular embodiments, providing the colloidal dispersion on top of the optical confinement layer, or embedded within the optical confinement layer, or between the substrate and the optical confinement layer corresponds to one of the following:
spin coating the colloidal dispersion;
drop casting the colloidal dispersion;
doctor blading the colloidal dispersion;
inkjet printing the colloidal dispersion;
depositing the colloidal dispersion via Langmuir-Blodgett or Langmuir-Schaeffer deposition techniques;
depositing the colloidal dispersion layer by layer.

In particular embodiments, the semiconductor film will be formed using spin coating. The film thickness is determined by both the concentration of the colloidal dispersion and the speed of spin coating. It is important to choose a concentration and a speed to minimize the material waste.

For example, decent uniformity is observed when spinning for one minute at 1000 rpm, to form a semiconductor film having a thickness in the range of 50-100 nm.

Alternatives to spin coating comprise several wet chemical deposition methods, such as for example:
drop casting, where a drop of colloidal dispersion is dripped on the surface of the substrate or on the surface of at least part of the optical confinement layer. Drop casting may result in the formation of a semiconductor film having a thickness larger than 100 nm and not demonstrating a high uniformity. However, drop casting can be useful in certain situations;
doctor blading, often from colloidal dispersions demonstrating a higher viscosity than colloidal dispersions processed via spin coating and/or drop casting. A droplet of the colloidal dispersion is spread out on the surface of the substrate or on the surface of at least part of the optical confinement layer using a sharp blade;
ink-jet printing, where a nozzle deposits droplets of the colloidal dispersion on the surface of the substrate or on the surface of at least part of the optical confinement layer;
Langmuir Blodgett or Langmuir-Schaeffer deposition which is useful to create very smooth monolayers or a controlled sequence of multilayers of the colloidal dispersion;
layer-by-layer deposition of the colloidal dispersion on the surface of the substrate or on the surface of at least part of the optical confinement layer. This allows the deposition of thicker films than the Langmuir Blodgett or Langmuir-Schaeffer deposition, but in a less controlled way. The substrate or at least part of the optical confinement layer is dipped repeatedly in the colloidal dispersion, washed in for example a non-solvent and then cycled again.

According to particular embodiments, the method further comprises the step of adding one or more ligands to the reaction chamber or reaction volume prior to and/or after forming the semiconductor film, thereby capping the bulk semiconductor nanocrystals and/or the bulk hetero nanocrystals with one or more ligands.

The semiconductor nanocrystals are capped in the colloidal dispersion with organic and/or inorganic ligands such as long chain carboxylates, phosphonic or even so-called atomic ligands. The ligands are not enabling for the optoelectronic device manufactured with the method according to the present disclosure. However, shorter ligands typically promote heat and charge transport in the formed semiconductor film leading to more stable and/or electrically more compatible and/or durable optoelectronic devices. Ligand exchange procedure further bring the semiconductor nanocrystals closer together.

It is typically implemented to exchange long organic ligands present during the synthesis of the colloidal dispersion with shorter ligands when the semiconductor film is already formed. This is for example usually done by dipping the formed semiconductor film in a solution that comprises the new ligands.

According to particular embodiments, the ligands are dissolved in a solvent. Alternatively, the ligands can be obtained by a gas phase treatment, for example in an atomic layer deposition (ALD) reactor or in a chemical vapor deposition (CVD) reactor.

According to particular embodiments, the ligands comprise one or more of the following:
one or more carboxylic acids or carboxylates;
one or more amines;
one or more thiols or thiolates;
one or more inorganic ligands;
one or more wide band gap insulator shells;
one or more atomic ligands;
one or more phosphonic acids or phosphonates;
one or more phosphinic acids or phosphinates;
one or more sulfonates.

An organic ligand for example corresponds to, but is not limited to: carboxylates, amines, thiols. An inorganic ligand for example corresponds to, but is not limited to: atomic ligands, such as Iodide, fluoride, chloride, etc., molecules, such as S²⁻, HS⁻, Se²⁻, HSe⁻, Te²⁻, HTe⁻, TeS₃²⁻, OH⁻, and NH₂⁻), etc. A ligand can for example comprise a wide band gap insulator shell, such as for example oxide, fluoride, nitride, etc.

According to particular embodiments, providing the optical confinement layer corresponds to growing a dielectric layer.

The dielectric layer for example comprises silicon nitride. Alternatively, the dielectric layer for example comprises silicon oxide. Alternatively, the dielectric layer comprises sapphire.

According to particular embodiments, providing the optical confinement layer corresponds to providing a layer configured to confine one or more optical modes in the semiconductor film.

According to particular embodiments, providing the optical confinement layer corresponds to providing a layer configured to add an optical feedback function to the one or more optical modes.

According to particular embodiments, the optical confinement layer comprises one or more of the following:
one or more waveguide structures formed in the plane of the layer;
one or more multi-layered waveguide structures;
one or more oxides;
one or more fluorides;
one or more nitrides;
one or more sulfides;
one or more metals.

For example, the optical confinement layer comprises silicon nitride which is grown with Chemical Vapor Deposition (CVD). The thickness and the density of the optical confinement layer can be varied to change the effective refractive index of the one or more confined optical modes. A dielectric layer comprising silicon nitride is for example grown using Plasma Enhanced Chemical Vapor Deposition (PECVD), at for example 270° C. and at a plasma frequency of for example 100 kHz. The dielectric layer has preferably a refractive index of around 2, compared to the refractive index of 1.4 of the silicon oxide substrate in the visible spectrum. Alternative materials for the optical confinement layer are in essence all those who are capable of confining light in the semiconductor film and/or adding an optical feedback function, e.g. through a periodic grating, looped and/or a mirror structure. Note that this covers in a way both in-plane waveguided structures for example DFB/DBR cavities, ring and disk resonators but also multi-layered stacks for vertical emission, such as for example Vertical External Cavity Surface Emitting Lasers (VECSELS) and Vertical Cavity Surface Emitting Lasers (VCSELS). The optical confinement layer could comprise one or more transparent materials—at the emission wavelength—such as for example oxides, fluorides, nitrides, sulfides, etc.

According to particular embodiments, the method further comprises the steps of forming the one or more integrated optical structures of the optical confinement layer; and wherein forming the one or more integrated optical structures corresponds to forming one or more feedback structures in the optical confinement layer.

After growing the optical confinement layer, a photoresist is patterned into one or more integrated optical structures. An integrated optical structure for example comprises one or more of the following: a 1-dimensional grating, a 2-dimensional grating, a 3-dimensional grating. A grating is understood as a periodic structure with a certain period or pitch. The patterned photoresist layer is then used to etch the period of the grating into the optical confinement layer. The combination of the grating period and the effective refractive index determines the wavelength of lasing operation of the manufactured optoelectronic device and the quality of the optical feedback. Silicon nitride can be very relevant for such applications since it is transparent in a wide spectral range. Other materials could be envisaged for the optical confinement layer with better thermal conductivity, like sapphire. We note that the feedback structures are not critical, i.e. the one or more feedback structures could also be a different periodic pattern such as for example a bulls-eye ring shaped pattern or for example a 1D grating with lines.

According to particular embodiments, a feedback structure is a grating, and wherein a period of the grating is comprised between 50 nm and 1000 nm.

Changing the grating pitch can change the wavelength of emission of the optoelectronic device manufactured with the method according to the present disclosure. Gratings with periods comprised between 50 nm and 1000 nm can be created. For example, a grating preferably comprises a period comprised between 210 nm and 350 nm for operation in the visible spectrum. The gratings are for example formed using electron beam lithography, also known as e-beam lithography. The e-beam photoresist used is for example AR-P 6200.09, and the photoresist is for example spun for a minute at 3000 rpm to form a layer of photoresist with a thickness close to 250 nm. The feedback structures are for example formed by etching the optical confinement layer through for example Reactive Ion Etching, also known as RIE, for example with a recipe specifically developed for silicon nitride etching using for example CF₄, H₂ and SF₆, with ratio of 80/5/3, at a pressure of 20 mTorr, and a power of 210 W. Inductively Coupled Plasma, also known as ICP etching, of the optical confinement layer is an alternative to the RIE etch. Alternatives to the electron beam lithography include one or more of the following: deep-UV lithography, nanoimprinting, standard optical lithography or additive manufacturing routines based on multi-photon polymerization.

According to a second example aspect of the present disclosure, there is provided an optoelectronic device obtainable by the method as defined by a first example aspect of the present disclosure.

According to a third example aspect of the present disclosure, there is provided an optically-pumped or electronically-pumped device with feedback structure comprising:
a substrate;
at least one optical confinement layer on top of the substrate, wherein one or more of the optical confinement layers comprise one or more integrated optical feedback structures; and
a semiconductor film on top of one or more of the optical confinement layers, or embedded within one of the optical confinement layers, or between the substrate and at least one of the optical confinement layers, or between at least two of the optical confinement layers, wherein the semiconductor film comprises semiconductor nanocrystals and/or bulk hetero nanocrystals, with a bulk hetero nanocrystal comprising at least two parts with one of these parts comprising a bulk semiconductor nanocrystal, with bulk semiconductor nanocrystals having a size in three independent directions larger than an upper limit for strong quantization of the corresponding bulk material, and with bulk semiconductor nanocrystals being defined as semiconductor nanocrystals having linear optical properties as determined by the corresponding bulk material composition, and not as determined by a size or diameter of the semiconductor nanocrystals because the semiconductor nanocrystals are not in a regime of quantum confinement and so demonstrate linear optical properties as determined by the corresponding bulk materials, wherein the linear optical properties comprise absorption spectra and photoluminescence spectra, wherein the semiconductor nanocrystals comprise:
   one or more II-VI semiconductor materials or alloys thereof;
   one or more III-V semiconductor materials or alloys thereof;
   one or more IV-VI semiconductor materials or alloys thereof;
   one or more Group IV semiconductor materials;
   one or more Group I-III-VI₂ semiconductor materials or alloys thereof; or
   any combinations thereof;
      and wherein the one or more optical confinement layers are configured to confine one or more optical modes in the semiconductor film and to add an optical feedback function to the one or more optical modes.

In the optoelectronic device according to the present disclosure, net stimulated emission can be obtained from bulk semiconductor nanocrystals and/or bulk hetero nanocrystals comprising a bulk semiconductor nanocrystal. An exceptionally high material gain—up to 50000 cm⁻¹—and long inverted state lifetime—up to 3 ns can be demonstrated in the optoelectronic device manufactured with the method according to the present disclosure. In the optoelectronic device according to the present disclosure, the semiconductor nanocrystals can be processed into semiconductor films to measure net modal gain and the semiconductor nanocrystals can be deposited on integrated optical structures such as for example 2D distributed feedback gratings. Lasing from such combined structures is achieved across for example a 50 nm wide wavelength range, set by the grating properties. Such bulk semiconductor nanocrystals therefore constitute a unique material to realize continuous wave optically pumped and electrically pumped solution-processed lasers. Further wavelength tuning is possible by changing the composition of the semiconductor nanocrystals, either within the II-VI family or by using different semiconductor families, such as III-V or IV-VI or Group IV or Group I-III-VI₂ compounds. Compared to truly bulk films of for example II-VI materials such as CdS, or another type of materials, the bottom-up approach of the method according to the present disclosure to realize the optoelectronic device enables bulk-like properties without the formation of typical bulk problems such as epitaxial strain, dislocations and other typical defects limiting the optical performance.

In the context of the present disclosure, a semiconductor film comprising bulk colloidal semiconductor nanocrystals is formed from a colloidal dispersion using the solution processable method according to the present disclosure. Each semiconductor nanocrystal demonstrates linear optical properties of the corresponding bulk semiconductor material of the nanocrystals. In other words, the semiconductor nanocrystals are not in a regime of confinement, hence demonstrating equivalent properties to a bulk material.

According to particular embodiments, the optoelectronic device is a laser. Alternatively, the optoelectronic device comprises an Amplified Spontaneous Emission (ASE) source.

Due to the high gain magnitude achieved by semiconductor nanocrystals with linear optical properties of corresponding bulk semiconductor materials according to the present disclosure, lasing and/or amplification can be achieved by the optoelectronic device according to the present disclosure with thin semiconductor films, for example having a thickness comprised between 6 nm and 1 μm.

According to particular embodiments, the semiconductor film comprises a material showing a material gain larger than 2000 cm⁻¹.

Looking at the most basic definitions of absorption and gain, one can define for the light with intensity I₀ entering a material with thickness L:

$$\frac{I}{{I}_{0}} = 1 {0}^{- A} = {e}^{- α L} \qquad ( 4 )$$

or for a scenario of net gain ‘g=−α’

$$\frac{I}{{I}_{0}} = {e}^{+ gL} \qquad ( 5 )$$

For a colloidal dispersion of semiconductor nanocrystals with a given concentration or volume fraction of active semiconductor material

$$f = \frac{{V}_{QD}}{{V}_{tot}} ,$$

the majority of space is solvent. Even if the colloidal dispersion is used to form a semiconductor film, there will still be air voids, ligands, . . . i.e. regions of non-semiconductor material that do not contribute to the absorption or amplification of light.

A composite medium, e.g. solvent with ligands and semiconductor nanocrystals, e.g. a film with air/ligands/semiconductor nanocrystals, is considered:

$$\frac{I}{{I}_{0}} = 1 {0}^{- A} = {e}^{- α L} = {e}^{- {μ}_{i} fL} \qquad ( 6 )$$

where

$$f = \frac{{V}_{QD}}{{V}_{tot}}$$

is the fraction of inorganic semiconductor material and L is the interaction length of light with the composite. When considering thin semiconductor films, or generally ‘waveguides’ with non-uniform distribution of light in the composite structure, this must be defined more carefully, being that ‘L’ has to represent an effective interaction length=‘Γ×L’, where Γ is the confinement factor for light in the semiconductor nanocrystals area/sub-layers. This brings us to:

$$α = {μ}_{i} f Γ \qquad ( 7 )$$

or for a situation of gain:

$$g = - {μ}_{i} f Γ \qquad ( 8 )$$

Note that μᵢ is the intrinsic absorption coefficient. The ‘material gain’ is then defined as g as follows:

$$- {μ}_{i} = {g}_{i} \qquad ( 9 )$$

The material gain can hence be seen as the gain per cm experienced by light traveling through the semiconductor film comprising semiconductor nanocrystals as if the volume fraction was 100% and all of the light was confined in the semiconductor film. The material gain is hence an ‘upper limit’ for the maximum achievable modal gain a photonic cavity can experience.

Finally, we note that gᵢ is wavelength, time and pump-power dependent. Often gᵢ is only referred to as the maximum value, being typically the value right after photoexcitation when all charges are still present.

According to particular embodiments, an inverted state lifetime for the semiconductor film is equal to or larger than 1 ns.

When a semiconductor is excited, either electrically or optically, charges are promoted to an excited state, here across the band gap. This causes the absorption spectrum of the semiconductor to change dramatically, being that the absorbance A after excitation will collapse to zero and eventually invert: A<0, whereas A0 of the unexcited semiconductor is obviously always positive. This situation of A<0 corresponds to net gain of the semiconductor, given that with a simple Beer-Lambert law:

$$\frac{I}{{I}_{0}} = 1 {0}^{- A} > 0 .$$

We define the gain lifetime as a wavelength or energy dependent quantity representing the ‘time window in which the material can sustain a net negative absorbance after an event of impulsive photo-excitation’. This “event” is shorter than any timescale relevant to the semiconductor film, such as intrinsic radiative or non-radiative recombination. More practically, it is the timeframe in which the semiconductor film can sustain a negative material absorption or positive material gain. This maximum is referred to as the ‘gain lifetime’.

According to particular embodiments, a tuning range of the gain spectrum of the semiconductor film is equal to or smaller than 20% of the band gap energy.

The bulk semiconductor nanocrystals according to the present disclosure provide sizable gain at photon energies above and below the band gap energy E0 of the bulk semiconductor nanocrystal. In particular, the photon energy range, seen as an energy window between a maximum and minimum energy, where net optical gain via the bulk semiconductor nanocrystals occurs “delta_E_gain” (=Egain,max~Egain,min) extends both to energies below the band gap (Egain,min<E0) and above it (Egain,max>E0). As an example, the normalized range “delta_E_gain”/E0 can exceed 0.2 for excitation densities in the bulk nanocrystals exceeding 10²⁰ cm⁻¹.

According to particular embodiments, a thickness of the semiconductor film is comprised between 6 nm and 200 nm, corresponding to 1 to 20 layers of the semiconductor nanocrystals.

Due to the high gain magnitude achieved by the semiconductor nanocrystals with linear optical properties of corresponding bulk materials according to the present disclosure, lasing can be achieved by the optoelectronic device according to the present disclosure with thin semiconductor films, for example having a thickness comprised between 6 nm and 1 μm, thereby limiting the amount of material needed and improving heat transport.

According to particular embodiments, a volume fraction of the semiconductor nanocrystals in the semiconductor film is larger than 0.1%, larger than 0.5%, larger or larger than 1%. The volume fraction of the semiconductor nanocrystals according to the present invention is considerably larger than the volume fraction of QDs in glass known in the art. The volume fraction of QDs in glass is typically ranging between 0.01 and 0.1%.

According to particular embodiments, the optoelectronic device operates at room temperature.

Net stimulated emission and lasing structures have been demonstrated in the prior art using perovskite nanocrystals, such as for example lead halide perovskites. In the following, state-of-art quantum dots—in confinement regime, so not bulk—and perovskite bulk-like quantum dots, i.e. beyond their respective Bohr diameter, are compared. This comparison is performed in the material context and the device context, where in both cases it is clear that a person skilled in the art would not be persuaded to shift towards bulk particles based on what can be read as metrics in the bulk perovskite QD literature. It would be clear for a person skilled in the art that the inverted lifetime and the material gain of the bulk perovskites nanocrystals are underwhelming, possibly because of a strong polaron formation due to the ionicity of the lattice. On the contrary, with the method and the optoelectronic device according to the present disclosure, an unexpected step is taken to rely on bulk-like materials for increased performance.

Comparing differences from a material point of view:

| | | | Gain | | | | |
|---|---|---|---|---|---|---|---|
| | | | coefficient | Max. Gain | | | |
| | Gain | k2 | at band gap | coefficient | Bandwidth | Threshold | Threshold |
| | lifetime | (cm³s⁻¹) | (cm⁻¹) | (cm⁻¹) | (nm) | (uJ/cm²) | (cm⁻³) |
| Semiconductor | 3 ns | 2.4e−10 | 20000 | 50000 | 100-120 | 9 | 2.5e18 |
| film according | | | | | | | |
| to the present | | | | | | | |
| disclosure | | | | | | | |
| (bulk CdS) | | | | | | | |
| Geiregat et | 100 ps | 2.2e−9 | No gain | 2000 | 15-20 | Ca. 20 | 1.6e18 |
| al. Bulk | | | at BG | | | | |
| perovskites | | | | | | | |
| Bisschop et | 800 ps | — | 2000 | 3000 | 80-100 | 15 | 4.9e18 |
| al. Confined | | | | | | | |
| CdSe/CdS QDs | | | | | | | |

Geiregat et al.: Using Bulk-like Nanocrystals To Probe Intrinsic Optical Gain Characteristics of Inorganic Lead Halide Perovskites, ACS Nano 2018, 12, 10, 10178-10188, https:doi.org/10.1021/acsnano.8b05092
Bisschop et al.: The Impact of Core/Shell Sizes on the Optical Gain Characteristics of CdSe/CdS Quantum Dots, ACS Nano 2018, 12, 9, 9011-9021, https:H/doi.org/10.1021/acsnano.8b02493

Gain lifetime and bandwidth are clearly worse for perovskites than for the semiconductor film according to the present disclosure.

Comparing performance of amplified spontaneous emission sources:

| | Type of | FWHM | Wavelength | Max gain | Threshold | Threshold |
|---|---|---|---|---|---|---|
| | device | (nm) | (nm) | (cm⁻¹) | (uJ/cm2) | (cm⁻³) |
| Optoelectronic | ASE | 60 | 460-530 | 5400 | 45 | 8.9e18 |
| device according | | | | | | |
| to the present | | | | | | |
| disclosure | | | | | | |
| (bulk CdS) | | | | | | |
| Yakunin et al. | ASE | 10 | 460-630 | 500 | 5-22 (fs), | — |
| perovskites | | | (different | | 450 (ns) | |
| | | | material | | | |
| | | | composition) | | | |
| Papagiorgis et | ASE | ~11 | 820 | 600 | 300 | — |
| al. perovskites | | | | | | |
| Zhu et al. | ASE | ~10 | 630 | 300 | 12 (fs), | — |
| Confinded | | | | | 270 (ns) | |
| CdSe/CdS QDs | | | | | | |

Yakunin et al.: Low-threshold amplified spontaneous emission and lasing from colloidal nanocrystals of caesium lead halide perovskites, Nature Communications volume 6, Article number: 8056 (2015)
Papagiorgis et al.: Efficient Optical Amplification in the Nanosecond Regime from Formamidinium Lead Iodide Nanocrystals, ACS Photonics 2018, 5, 3, 907-917, https://doi.org/10.1021/acsphotonics.7b01159
Zhu et al.: On-Chip Single-Mode Distributed Feedback Colloidal Quantum Dot Laser under Nanosecond Pumping, ACS Photonics 2017, 4, 10, 2446-2452, https: H/doi.org/10.1021/acsphotonics.7b00644

Comparing performance of lasers:

| | Type of | FWHM | Wavelength | Max gain | Threshold | Threshold |
|---|---|---|---|---|---|---|
| | device | (nm) | (nm) | (cm⁻¹) | (uJ/cm2) | (cm⁻³) |
| Optoelectronic | 2D | ~0.5 | 470-530 | — | 17 | 3.3e18 |
| device according | DFB | | (different | | | |
| to the present | | | devices) | | | |
| disclosure | | | | | | |
| (bulk CdS) | | | | | | |
| Yakunin et al. | WGM | 1.1 | 525-535, | — | — | — |
| perovskites | | | 480-485 | | | |
| Price et al. | WGM | 2 | 500-540 | — | 1100 | |
| perovskites | | | | | | |
| Wang et al. | VCSEL | 0.6 | 505-550 | — | 10 | — |
| perovskites | | | | | | |
| Adachi et al. | 2D | 0.7 | 643 | — | 60 (us | — |
| Confined | DFB | | | | lasing) | |
| CdSe/CdS QDs | | | | | | |

where *fs = femtosecond pulsed excitation, ns = nanosecond pulsed excitation.

Price et al.: Whispering-Gallery Mode Lasing in Perovskite Nanocrystals Chemically Bound to Silicon Dioxide Microspheres, J. Phys. Chem. Lett. 2020, 11, 17, 7009-7014, https://doi.org/10.1021/acs.jpclett.0c02003
Wang et al.: Solution-Processed Low Threshold Vertical Cavity Surface Emitting Lasers from All-Inorganic Perovskite Nanocrystals, Advanced Functional Materials, Volume 27, Issue 13, Apr. 5, 2017, U.S. Pat. No. 1,605,088
Adachi et al., Microsecond-sustained lasing from colloidal quantum dot solids, Nature Communications volume 6, Article number: 8694 (2015)

Clearly, from the above results, perovksite QDs present no significant improvement over existing II-VI confined QD technology since they provide comparable gain thresholds, shorter gain lifetimes and even smaller gain coefficients. This makes the conclusion that using bulk semiconductor nanocrystals are not per se interesting to the person skilled in the art, especially when it is well known that many defects, impurities, etc. existing when working with bulk materials will deteriorate the optical performance.

What eventually makes materials like the semiconductor film according to the present disclosure work so well in bulk is that the correlations between charges in such excitonic semiconductors are much stronger than in perovskites. This leads to more pronounced redshifts of the absorption spectrum upon photo-excitations, which results in the favorable gain metrics of bulk semiconductor nanocrystals. This effect is known as band gap renormalization and is expressed as an energy Δ_{BGR} shift of the optical absorption spectrum. This shift depends on the temperature of the electron/hole gas and the density of carriers present. To exploit the beneficial effects, the shift Δ_{BGR} should at least exceed the exciton binding energy of the corresponding bulk material.

### BRIEF DESCRIPTION OF THE DRAWINGS

Some example embodiments will now be described with reference to the accompanying drawings:

FIG. 1 illustrates the colloidal synthesis of bulk semiconductor CdS nanocrystals.

FIG. 2 illustrates the synthesis of bulk hetero nanocrystals comprising a core/shell structure of CdS/ZnS, wherein CdS comprises a bulk semiconductor nanocrystal.
core/shell bulk semiconductor CdS/ZnS bulk hetero nanocrystals.

FIGS. 3a, 3b, 3c and 3d illustrate the absorption spectra and photoluminescence spectra of semiconductor CdS nanocrystals as synthesized above, showing the evolution of the spectra for increasing particle size and the invariance above do of the optical properties.

FIG. 4a shows a sizing curve procedure of wurtzite CdS nanocrystals showing energy of the band gap versus the particle size as determined by absorption spectroscopy and transmission electron microscopy, respectively.

FIG. 4b shows the absorption spectrum (solid black) and the spontaneous photoluminescence spectrum (filled grey) of 12 nm bulk semiconductor CdS nanocrystals.

FIGS. 5a and 5b show the material gain gᵢ spectra, taken 3 picoseconds after 400 nm photo-excitation, and the gain decay of bulk semiconductor CdS nanocrystals for varying pump conditions, probed at the band gap transition wavelength of 517 nm. The gain lifetime is the longest time for which the gain can remain net positive as indicated by the vertical dashed line.

FIG. 6 shows the band gap renormalization energy Δ_{BGR} normalized (left axis) to the exciton binding energy Rx of the corresponding bulk material and not normalized (right axis), for increasing ratio of the carrier density n (in cm⁻³) and the temperature of the carriers T (in Kelvin) in the bulk semiconductor CdS nanocrystals.

FIG. 7 shows the amplified spontaneous emission spectra at fixed stripe length of 3 mm using 400 nm femtosecond (110 fs) pumping.

FIG. 8 shows the integrated counts of the total spectrum (black) and the separate ASE bands (see inset) (grey), showing clear threshold behavior.

FIG. 9 shows the variable stripe length measurements at different wavelengths (472, 473, 503 and 504 nm) at fixed pump power.

FIG. 10 shows the extracted intrinsic gain from thin film variable stripe length measurements versus wavelength at different optically generated carrier densities.

FIGS. 11a, 11b and 11c depict a cross-section of example embodiments of an optoelectronic device according to the present disclosure.

FIG. 12 depicts a proof-of-concept of an optically pumped laser manufactured with the method according to the present disclosure.

FIG. 13 shows the emission spectra of optically pumped (with 450 nm) cavities made with bulk heteronanocrystals comprising a core/shell structure of CdS/ZnS nanocrystals, where light is collected from the top. The grating uses a 300 nm pitch.

FIG. 14 shows the integrated light output versus pump fluence for the laser in FIG. 13.

FIG. 15 shows the emission spectra of optically pumped (450 nm) cavities made with bulk CdS/ZnS nanocrystals, collected from the top, here shown using a variation of the grating period showing lasing across the 485-525 nm band from the same CdS/ZnS film composition.

FIG. 16 shows the threshold energy (in micro joules per area in square centimeters) required for laser action under pulsed excitation for the lasers operating at different wavelengths made with bulk hetero nanocrystals comprising a core/shell structure of CdS/ZnS, collected from the top, here shown using a variation of the grating period to show lasing across the 485-525 nm band.

FIG. 17 shows embodiments of Vertical Cavity Surface Emitting Lasers (VCSELS) and Vertical External Cavity Surface Emitting Lasers (VECSEL).

FIG. 18 shows a Distributed Feedback Laser (DFB) laser structure.

FIG. 19 shows ring and disk lasers.

### DETAILED DESCRIPTION OF EMBODIMENT(S)

The present invention will be described with respect to particular embodiments and with reference to certain drawings but the invention is not limited thereto but only by the claims. The drawings are only schematic and are non-limiting. The size of some of the elements in the drawing may be exaggerated and not drawn on scale for illustrative purposes. The dimensions and the relative dimensions do not correspond to actual reductions to practice of the invention.

It will furthermore be understood by the reader of this patent application that the words “comprising” or “comprise” do not exclude other elements or steps, that the words “a” or “an” do not exclude a plurality, and that a single element, such as a computer system, a processor, or another integrated unit may fulfil the functions of several means recited in the claims. Any reference signs in the claims shall not be construed as limiting the respective claims concerned. The terms “first”, “second”, third”, “a”, “b”, “c”, and the like, when used in the description or in the claims are introduced to distinguish between similar elements or steps and are not necessarily describing a sequential or chronological order. Similarly, the terms “top”, “bottom”, “over”, “under”, and the like are introduced for descriptive purposes and not necessarily to denote relative positions. It is to be understood that the terms so used are interchangeable under appropriate circumstances and embodiments of the invention are capable of operating according to the present invention in other sequences, or in orientations different from the one(s) described or illustrated above.

When referring to the endpoints of a range, the endpoints values of the range are included. The term ‘and/or’ when listing two or more items, means that any one of the listed items can by employed by itself or that any combination of two or more of the listed items can be employed.

### Synthesis of Bulk Semiconductor Nanocrystals

The synthesis of bulk semiconductor CdS nanocrystals and/or of bulk hetero nanocrystals comprising a core/shell structure with CdS as core and ZnS as shell bulk is described below.

### Example 1: Synthesis of Bulk Semiconductor CdS Nanocrystals

Chemicals used: cadmium oxide (CdO)—99.5% (Chem-Lab NV), sulfur (S)—pure≥99.5% (Sigma Aldrich), zinc oxide (ZnO)—99.9% trace metal basis (Sigma Aldrich),—tri-n-octylphosphine (TOP)—≥97% (Strem Chemicals), oleic acid (OA)—tech. 90% (Alfa Aesar), 1-octadecene (ODE)—tech. 90% (Alfa Aesar), toluene (tol)—99.7% (Chem-Lab NV), 2-propanol—99.8% (Chem-Lab NV). All chemicals were used as is without further purification.

Preparation of Cd-oleate Precursor (0.5 M): In a 50 ml three neck flask, 1.024 g (8 mmol) CdO, 8 ml of oleic acid and 8 ml of ODE were added. The flask was put under vacuum at 120° C. for approximately 1 hour to remove residual water. The temperature was then increased to 300° C. under N₂. As soon as the mixture became clear (~5 minutes) the flask was cooled down naturally to room temperature and the resulting mixture was stored in a 20 ml vial in the glovebox for further use.

Preparation of TOP-S Precursor (0.5 M): The preparation of the TOP-S solution was done within the glovebox. 32 mg (1 mmol) of elemental S were weighed in a 4 ml vial and 2 ml TOP were then inserted. The vial was heated under stirring at 100° C. until the sulfur was fully complexed and the solution turned clear. The vial was then cooled down and kept in the glovebox for further use.

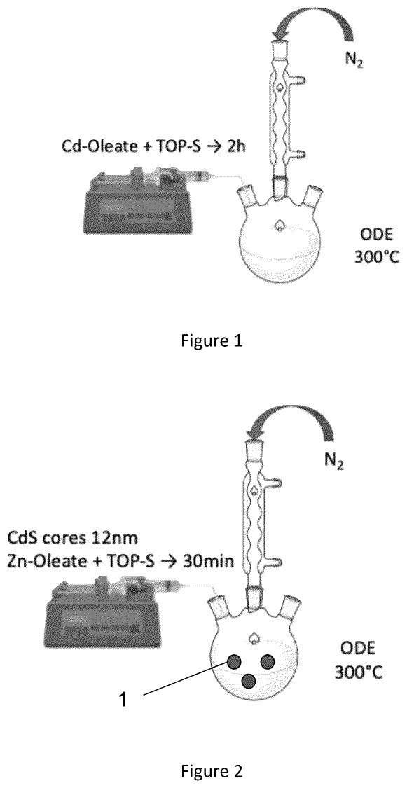

Synthesis of gCdS Quantum Dots (gCdS QDs): In a 50 ml three neck flask, as illustrated in FIG. 1, 8 ml of ODE were inserted and heated under vacuum at 110° C. for 1 hour to remove residual water. The flask was then put under N₂ and heated to 300° C. Equimolar solutions of the TOP-S and the Cd-oleate precursors were mixed in a 5 ml syringe and, using a syringe pump, the solution was injected continuously with a 2 mL/hour rate. Aliquots of 500 L were taken and quenched with 500 L toluene to monitor the QDs growth rate through PL and TEM. At the end of the injection, the flask was left to cool down to room temperature. It was observed that using 4 ml of the 1:1 TOP-S:Cd-oleate solution results in QDs with size dispersion ranging from 7 nm to 12 nm during the 2 hour reaction time. For this reason, size selective precipitation was then performed by adding 2-propanol in the aliquots and the final mixture until the solutions just turned cloudy. The resulting suspension was then centrifuged at 4500 rpm and the precipitate (larger quantum dots) was then redispersed in 3 ml toluene while the smaller quantum dots remained in the supernatant.

### Example 2: Synthesis of Bulk Hetero Nanocrystals Having a Core/Shell Structure with CdS as Core and ZnS as Shell

Preparation of Zn-oleate Precursor (0.5M): In a 50 ml three neck flask, 0.6511 g (8 mmol) ZnO, 8 ml of oleic acid and 8 ml of ODE were added. The flask was put under vacuum at 120° C. for approximately 1 hour to remove residual water. The temperature was then increased to 300° C. under N₂. As soon as the mixture became clear (~35 minutes) the flask was cooled down naturally to room temperature and the resulting mixture was stored in a 20 ml vial in the glovebox for further use.

Preparation of TOP-S Precursor (0.5M): The preparation of the TOP-S solution was done within the glovebox. 32 mg (1 mmol) of elemental S were weighed in a 4 ml vial and 2 ml TOP were then inserted. The vial was heated under stirring at 100° C. until the sulfur was fully complexed and the solution turned clear. The vial was then cooled down and kept in the glovebox for further use.

Synthesis of gCdS/ZnS Quantum Dots (gCdS/ZnS QDs): As illustrated in FIG. 2, for shelling, after the 2 hours reaction time the crude gCdS core solution was left for an additional 10 minutes to have all the remaining unreacted precursors consumed. The presynthesized bulk nanocrystals 1 are thereby acting as seeds for core/shell growth. The syringe was exchanged to contain equimolar solutions of Zn-oleate and TOP-S. Using a syringe pump and the same 2 ml/hour injection rate, the solution was injected and aliquots were taken to monitor the growth rate of the shell through TEM. It takes approximately 30 minutes to grow a ~2 nm ZnS shell around the QDs. Size selective precipitation using 2-propanol was done to remove the smaller QDs. Then a 2-step purification was done using a 1:1 ratio of IPA:MeOH as antisolvents, centrifuging for 5 minutes at 4500 rpm and redispersing in toluene.

As described above in the context of the present disclosure, bulk semiconductor nanocrystals also referred as bulk three-dimensional or bulk 3D semiconductor nanocrystals are nanocrystals exhibiting linear optical properties determined by the material composition and not determined by their nanocrystal size/diameter.

Bulk semiconductor nanocrystals have preferably a size in three independent directions larger than an upper limit d₀ for strong quantization, wherein d₀ corresponds to the exciton Bohr diameter of the corresponding bulk material. The calculation method is described above.

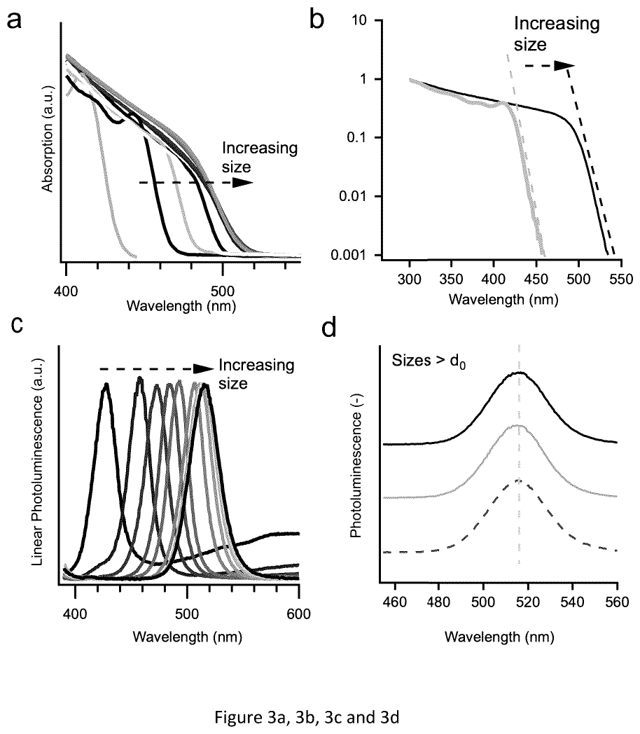

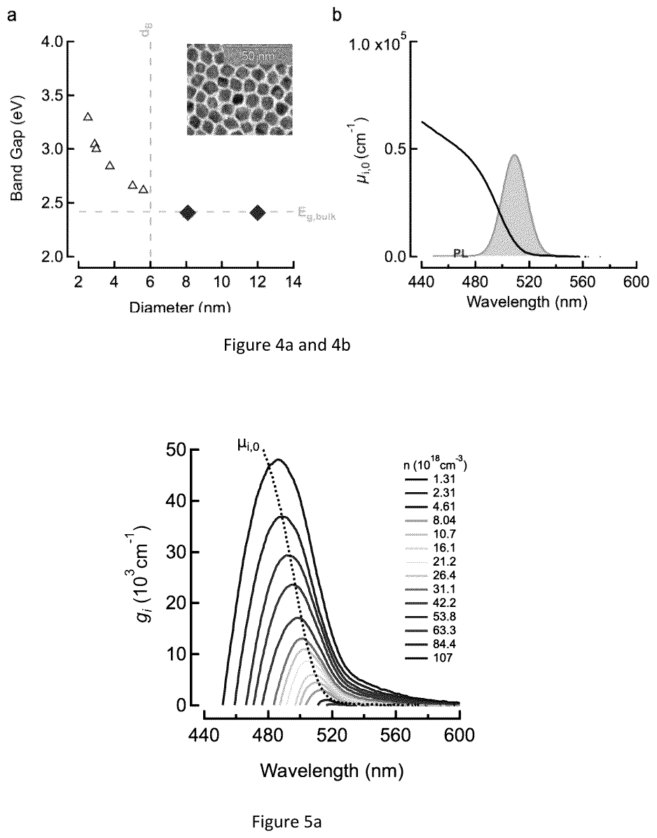

The concept of bulk semiconductor nanocrystals according to the present disclosure is further illustrated in FIG. 3 a-d and in FIG. 4a-b.

FIG. 3a shows the absorption spectra of semiconductor CdS nanocrystals for increasing size. The semiconductor CdS nanocrystals are synthesized as described above. As a certain size d0 is crossed all spectra overlap indicating the bulk limit is reached and confinement effects wash out.

FIG. 3b shows a detail of the absorption spectra of the smallest (grey) and largest particles (black) on a logarithmic scale for the absorption. The dashed lines indicate the determination procedure of the semiconductor band gap.

FIG. 3c shows the photoluminescence of semiconductor CdS nanocrystals for increasing sizes. As a certain size d0 is crossed all spectra overlap, indicating the bulk limit is reached. The properties are now no longer determined by size but by the composition, as for bulk.

FIG. 3d shows the photoluminescence spectra of CdS nanocrystals for sizes beyond do. One clearly observes all the spectra are identical indicating the optical properties are no longer dictated by the size of the crystallites.

FIG. 4a illustrates the sizing curve procedure of wurtzite CdS nanocrystals showing energy of the band gap versus the particle size, indicating the regime of confinement (triangles) and that of bulk-like particles (diamonds). The inset of FIG. 4a shows a transmission electron microscopy image of the nanocrystals as used to determine the diameter.

FIG. 4b shows the optical properties of 12 nm bulk semiconductor CdS nanocrystals, synthesized as described above, by showing the absorption spectrum (solid black) and the spontaneous photoluminescence (filled).

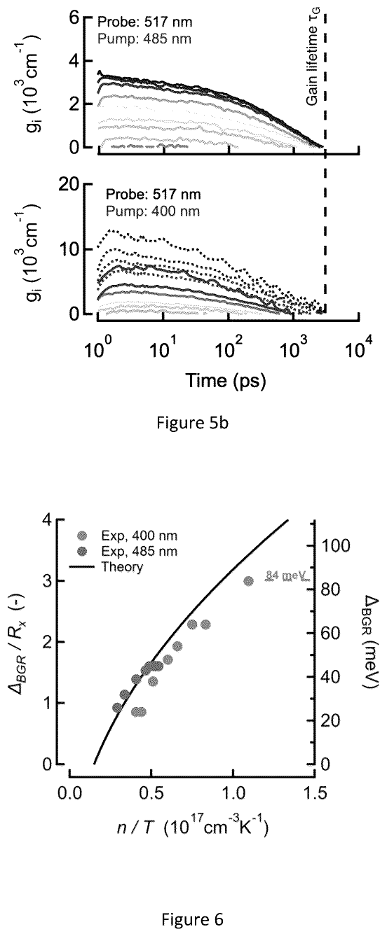

FIGS. 5a and 5b show the material gain gᵢ spectra and the gain decay of bulk semiconductor CdS nanocrystals, synthesized as described above. In FIG. 5a material gain gᵢ spectra of bulk semiconductor CdS nanocrystals, at 3 ps after increasing photo-excitation with 400 nm are shown. A net gain window opens up near the band gap at n=10¹⁸ cm⁻³ only to increase, without any signs of saturation, to nearly 50.000 cm⁻¹ at shorter wavelengths. The gain simultaneously also redshifts away from the linear absorption due to band gap renormalization, showing net stimulated emission at wavelengths where there is no linear absorption, being from 520 nm to 600 nm. FIG. 5b shows the dynamics of the material gain at the band gap after 485 nm (top) and 400 nm (bottom), pumping. A net gain up to 2.9 ns is observed, both for resonant (485 nm) and off-resonant (400 nm) excitation. This time window is defined as the gain lifetime.

FIG. 6 shows the band gap renormalization energy Δ_{BGR} normalized (left axis) to the exciton binding energy Rₓ of the corresponding bulk material and not normalized (right axis), for increasing ratio of the carrier density n (in cm⁻³) and the temperature of the carriers T (in Kelvin) in the bulk semiconductor CdS nanocrystals.

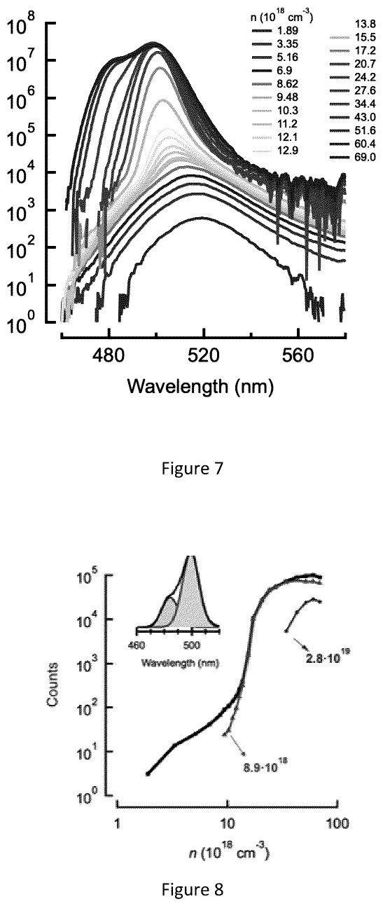

Proof of concept of amplified spontaneous emission through bulk semiconductor CdS nanocrystals according to the present invention is shown in FIG. 7. In particular, FIG. 7 shows the variable stripe length (VSL) setup used where ASE (amplified spontaneous emission) is collected from the side of a slab waveguide structure under a variable line illumination. Using a 400 nm pump, clear amplification characteristics shown on the right is obtained, where a strongly supra-linear light output is observed. A clear threshold of n=8.9 10¹⁸ cm⁻³ is observed for the main ASE lobe. A higher threshold of 2.8 10¹⁹ cm⁻³ characterizes the second high energy gain band. Several observations of the ASE contrast with the numerous reports on other solution processable confined QD systems. Indeed, the ASE output bursts over 4 order of magnitudes over the spontaneous emission, and does not seem to saturate or produce the typical narrow lines typical for quantum confined 2 level systems.

FIG. 8 shows the integrated counts of the total spectrum (black) and the separate ASE bands, showing clear threshold behavior. Horizontal axis is expressed as created carrier density n generated in the bulk nanocrystals

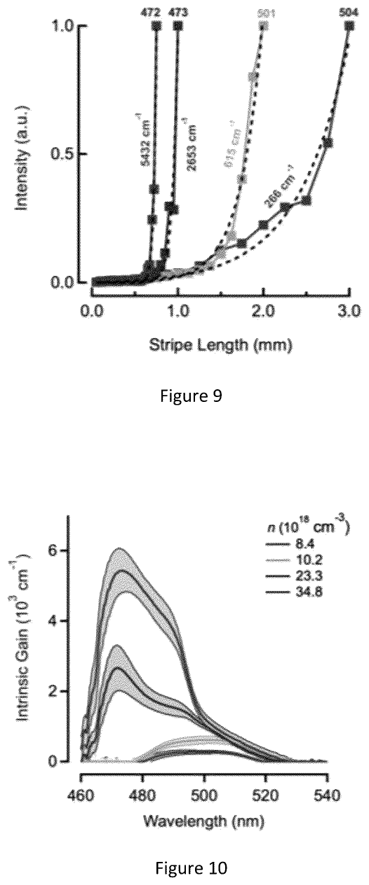

FIG. 9 shows the variable stripe length measurements at different wavelengths (472, 473, 503 and 504 nm) at fixed pump power, showing supra-linear increase with increasing amplifier (stripe) length in mm. Dashed lines indicate fits to extract the material gain coefficients.

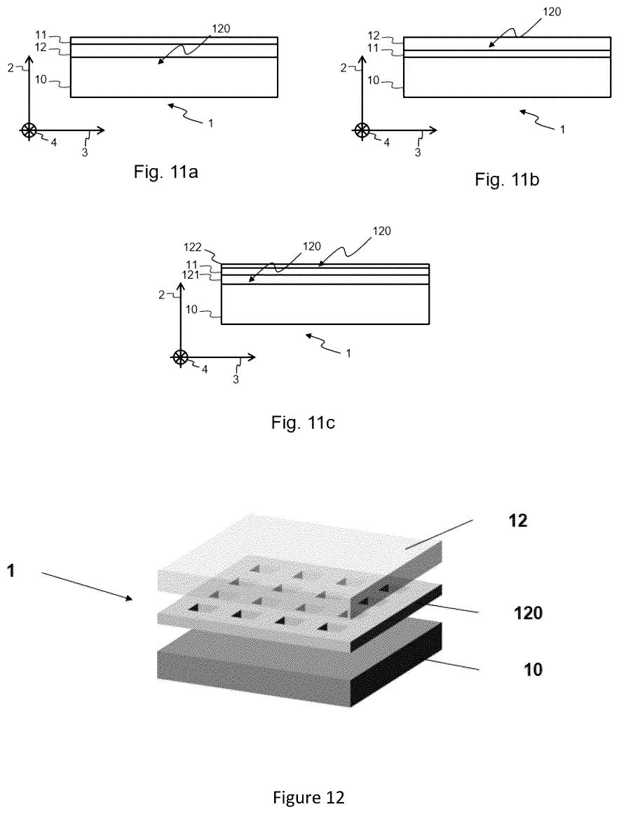

FIG. 10 shows the extracted intrinsic gain from thin film measurements versus wavelength at different optically generated carrier densities.

FIGS. 11a, 11b and 11c schematically depict a cross-section of example embodiments of an optoelectronic device 1 according to the present disclosure. The optoelectronic device extends along a longitudinal direction 3. In FIG. 11a, the optoelectronic device 1 comprises a substrate 10, at least one optical confinement layer 12 on top of the substrate 10 along the traverse direction 2, wherein one or more of the optical confinement layers 12 comprise one or more integrated optical structures 120 configured to confine one or more optical modes; and a semiconductor film 11 on top of one or more of the optical confinement layers 12 along the traverse direction 2. The semiconductor film 11 comprises a colloidal dispersion, wherein the colloidal dispersion comprises semiconductor nanocrystals with linear optical properties as determined by the corresponding material composition, wherein the semiconductor nanocrystals comprise: one or more II-VI semiconductor materials or alloys thereof; one or more III-V semiconductor materials or alloys thereof; one or more IV-VI semiconductor materials or alloys thereof; one or more Group IV semiconductor materials or alloys thereof; one or more Group I-III-VI₂ semiconductor materials or alloys thereof; or any combinations thereof. In FIG. 11b, the optoelectronic device 1 comprises a substrate 10, at least one optical confinement layer 12 on top of the substrate 10 along the traverse direction 2, wherein one or more of the optical confinement layers 12 comprise one or more integrated optical structures 120 configured to confine one or more optical modes; and a semiconductor film 11 formed between the substrate 10 and the optical confinement layer 12 along the traverse direction 2. The semiconductor film 11 comprises a colloidal dispersion, wherein the colloidal dispersion comprises semiconductor nanocrystals with linear optical properties as determined by the corresponding material composition, wherein the semiconductor nanocrystals comprise: one or more II-VI semiconductor materials or alloys thereof; one or more III-V semiconductor materials or alloys thereof; one or more IV-VI semiconductor materials or alloys thereof; one or more Group IV semiconductor materials or alloys thereof; one or more Group I-III-VI₂ semiconductor materials or alloys thereof; or any combinations thereof. In FIG. 11c, the optoelectronic device 1 comprises a substrate 10, at least optical confinement layer 12 on top of the substrate 10 along the traverse direction 2, wherein one or more of the optical confinement layers 12 comprise one or more integrated optical structures 120 configured to confine one or more optical modes, and wherein the optical confinement layer 12 comprises a first optical confinement section 121 formed on top of the substrate 10 along the traverse direction 2, wherein the first optical confinement section 121 comprises one or more integrated optical structures 120 configured to confine one or more optical modes; a semiconductor film 11 embedded within one of the optical confinement layers, or between at least two of the optical confinement layers. In other words, the semiconductor film 11 is formed on top of the first optical confinement section 121 of the optical confinement layer 12 along the traverse direction 2, wherein the semiconductor film 11 comprises a colloidal dispersion, wherein the colloidal dispersion comprises semiconductor nanocrystals with linear optical properties as determined by the corresponding material composition, wherein the semiconductor nanocrystals comprise: one or more II-VI semiconductor materials or alloys thereof; one or more III-V semiconductor materials or alloys thereof; one or more IV-VI semiconductor materials or alloys thereof; one or more Group IV semiconductor materials or alloys thereof; one or more Group I-III-VI₂ semiconductor materials or alloys thereof; or any combinations thereof; wherein the optical confinement layer 12 further comprises a second optical confinement section 122 formed on top of the semiconductor film 11 along the traverse direction 2, wherein the second optical confinement section 122 optionally comprises one or more integrated optical structures 120 configured to confine one or more optical modes.

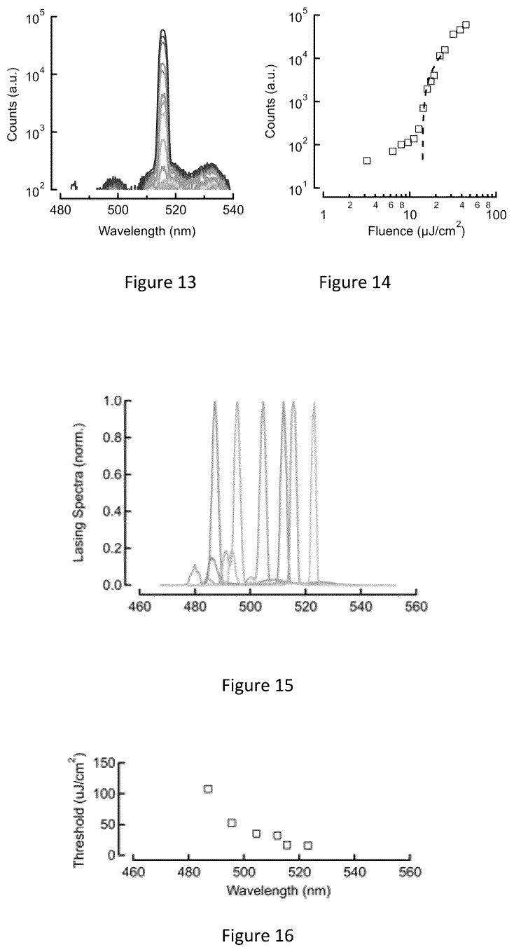

FIG. 12 depicts a proof-of-concept of an optically pumped laser 1 manufactured with the method according to the present disclosure. FIG. 13 and FIG. 14 respectively show the emission spectra of optically pumped (450 nm) cavities made with bulk semiconductor CdS nanocrystals, collected from the top, using a 300 nm pitch grating and the integrated light output versus pump fluence;

FIG. 12 shows the feedback structure used, which consists of a substrate 10, an optical confinement layer 12 comprising integrated optical structures 120. The integrated optical structures 120 comprise a 2D in-plane grating etched out of silicon nitride formed on top of the substrate. The laser 1 further comprises a semiconductor film 11 formed on top of the optical confinement layer 12. A thin (50 nm) layer of a colloidal dispersion comprising semiconductor nanocrystals comprising CdS is spin coated on top of the optical confinement layer to form the semiconductor film 11.

The integrated optical structures 120 of the optical confinement layer 12 are then pumped using a 450 nm femtosecond laser using a 100×100 micron spot size (see FIG. 13). Using a pitch A of 300 nm, the light emitted is centered at 517 nm and increases supra-linear with in excitation fluence for over 3 orders of magnitude (see FIG. 14). A clear threshold at 17 J/cm² is observed while at high fluence the emission does not show strong saturation as observed for other QD lasers. The latter can be assigned to the increased radiative rate at high density, opposed to Auger losses in confined QD lasers taking over at high pump fluence.

By varying the pitch, similar lasing action can be obtained across the 490-520 nm window, albeit with increasing threshold fluence going into the blue. The latter is expected given the gain threshold is lowest for the band gap region, see FIG. 13, where the BGR is dominant. The spectra of the largest pitch samples also display a second mode which is much less confined in the QD layer, yet due to the high gain coefficients obtained in CdS across the spectrum, the second mode can also start lasing.

FIG. 15 shows the emission spectra of optically pumped (450 nm) cavities made with bulk CdS/ZnS nanocrystals, collected from the top, here shown using a variation of the grating period showing lasing across the 480-520 nm band from the same CdS/ZnS film composition..

FIG. 16 shows the threshold energy (in micro joules per area in square centimeters) required for laser action under pulsed excitation for the lasers operating at different wavelengths made with bulk hetero nanocrystals comprising a core/shell structure having CdS as core and ZnS as shell, collected from the top, here shown using a variation of the grating period to show lasing across the 485-525 nm band.

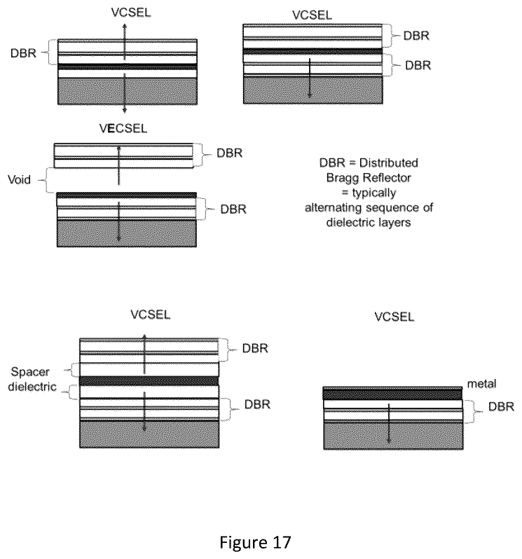

FIG. 17 shows embodiments of Vertical Cavity Surface Emitting Lasers (VCSELS) and Vertical External Cavity Surface Emitting Lasers (VECSELS).

The VCSELS shown in FIG. 17 have emission perpendicular to the surface and are formed on a substrate (grey area). The vertical cavity is formed by two mirrors surrounding the nanocrystal gain medium, indicated by the black area. A spacer layer can be added to position the active nanocrystal layer that guide the optical mode in the vertical direction, typically (but not exclusively) these mirrors are dielectric multi-layers forming distributed bragg reflectors (DBRs). A highly reflective metallic mirror can also be used at the expense of more loss per round trip. Some of the possibilities using dielectric DBRs are shown in the FIG. 17.

The VECSEL shown in FIG. 17 uses the same principle as VCSELs, but one of the mirrors is not attached to the sample with the gain layer and/or spacer material. It is held in place externally and can be controlled to change the cavity's properties at will.

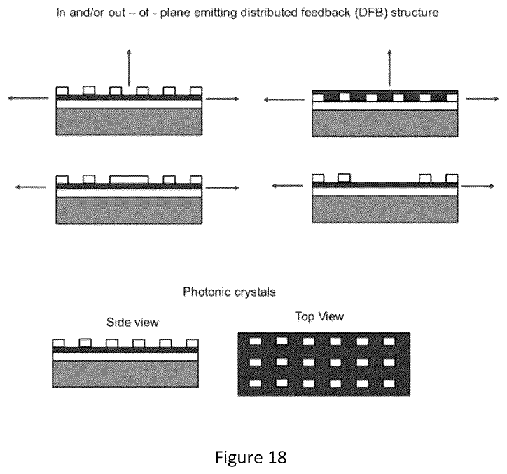

FIG. 18 shows a Distributed Feedback Laser (DFB) laser structure. A DFB laser uses a planar grating to confine light. Gratings impose restrictions on how the light is allowed to move, and can be designed as such to create a cavity. The shape of the unit cell, duty cycle, and period (or pitch) can be controlled to change grating properties such as bandwidth and reflectivity of the optical band gap, i.e. the spectral window where the feedback is provided. In particular embodiments two gratings are separated by a certain length to create stronger confinement and/or optical gain. It is possible to first made a grating and then overcoat the grating. In other embodiments, a grating is created after the embedding of the gain layer. Depending on the order of the grating, there will be confinement in the plane or surface emission (2^{nd} order gives surface emission and in-plane confinement, 1^{st} order only in-plane). The grating can have periodicity in 1 dimension, 2 dimensions or 3 dimensions. Some of the geometries are shown in the FIG. 18, where the system with periodicity in 2 and 3 dimensions is often referred to as a photonic crystal laser.

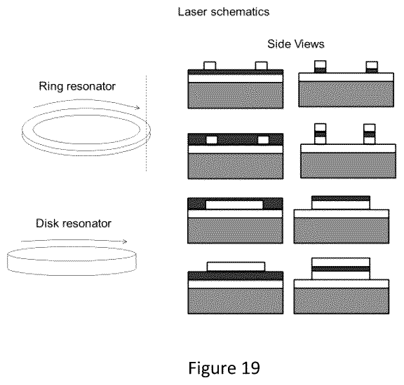

FIG. 19 shows ring and disk lasers. Ring or disk lasers have a cavity which is curled up to form a closed loop. The optical mode in these types of lasers is a “whispering gallery mode”, it travels in circles around the cavity, near the edge. The difference between a ring and a disk laser is the filling of the center of the resonator. The layer stack can be modified to produce different structures as shown in the FIG. 19. Again, the black area indicates the position of the nanocrystal gain medium.

Although the present invention has been illustrated by reference to specific embodiments, it will be apparent to those skilled in the art that the invention is not limited to the details of the foregoing illustrative embodiments, and that the present invention may be embodied with various changes and modifications without departing from the scope thereof. The present embodiments are therefore to be considered in all respects as illustrative and not restrictive, the scope of the invention being indicated by the appended claims rather than by the foregoing description, and all changes which come within the scope of the claims are therefore intended to be embraced therein.

1.-14. (canceled)

15. A method of manufacturing an optically-pumped or electrically-pumped device with feedback structure, the method comprising the steps of:
providing a substrate;
providing at least one optical confinement layer on top of the substrate, wherein one or more of the optical confinement layers comprise one or more integrated optical feedback structures;
forming a colloidal dispersion comprising bulk semiconductor nanocrystals and/or bulk hetero nanocrystals, with a bulk hetero nanocrystal comprising at least two parts with one of these parts comprising a bulk semiconductor nanocrystal, with bulk semiconductor nanocrystals having a size in three independent directions larger than larger an upper limit for strong quantization of the corresponding bulk material, and with bulk semiconductor nanocrystals being defined as semiconductor nanocrystals having linear optical properties as determined by the corresponding bulk material composition, and not as determined by a size or diameter of the semiconductor nanocrystals because the semiconductor nanocrystals are not in a regime of quantum confinement and so demonstrate linear optical properties as determined by the corresponding bulk materials,
wherein the linear optical properties comprise absorption spectra and photoluminescence spectra, wherein the bulk semiconductor nanocrystals comprise:
one or more II-VI semiconductor materials or alloys thereof;
one or more IT-V semiconductor materials or alloys thereof;
one or more IV-VI semiconductor materials or alloys thereof;
one or more Group IV semiconductor materials or alloys thereof;
one or more Group I-III-VI₂ semiconductor materials or alloys thereof; or
any combinations thereof; and
providing the colloidal dispersion:
on top of one or more of the optical confinement layers, or
embedded within one of the optical confinement layers, or
between at least two of the optical confinement layers, or
between the substrate and at least one of the optical confinement layers,
thereby forming a semiconductor film from the colloidal dispersion, wherein the one or more optical confinement layers are configured to confine one or more optical modes in the semiconductor film and to add an optical feedback function to the one or more optical modes, and thereby forming the optically-pumped or electrically-pumped device with the optical integrated feedback structures.

16. The method according to claim 15, wherein the bulk semiconductor nanocrystals have a size in three independent directions larger than an upper limit d₀ for strong quantization,
wherein d₀ corresponds to the exciton Bohr diameter of the corresponding bulk material calculated according to relation (a):
$${d}_{0} = 8 π \frac{{ε}_{∞} {ε}_{0} {ℏ}^{2}}{μ {m}_{0} {e}^{2}} \qquad ( a )$$
wherein ε₀ is the permittivity of the vacuum, h is Planck's constant, m₀ is the free electron mass, e the elementary charge, ε_{∞} is the high-frequency dielectric constant and y is the reduced effective mass of the corresponding bulk material.

17. The method according to claim 15, wherein the bulk semiconductor nanocrystals have a size in three independent directions larger than an upper limit d₀ for strong quantization,
wherein do is obtained from fitting an experimental dependence of the bulk semiconductor nanocrystals band gap E₁ on the size d of the bulk semiconductor nanocrystals to a generic sizing curve according to relation (b):
$${E}_{1} ( d ) = \frac{1}{2} [ {E}_{0} + \sqrt{{E}_{0}^{2} + 8 \vert {E}_{0} \vert {απ}^{2} \frac{{R}_{y} {a}_{0}}{{ε}_{∞} {d}_{0}} {{e}^{- \frac{d}{{d}_{0}}} [ 1 - {e}^{- \frac{d}{{d}_{0}}} ]}^{- 2}} ] \qquad ( b )$$
wherein d₀ is the only adjustable parameter while E₀ is the band gap of the corresponding bulk material, α is a constant number equal to 0.7, R_{y} is the Rydberg energy of the corresponding bulk material, a₀ is the Bohr radius of the hydrogen atom, ε_{∞} is the high-frequency dielectric constant of the corresponding bulk material.

18. The method according to claim 15, wherein the colloidal dispersion comprises bulk hetero nanocrystals comprising at least one core and at least one shell surrounding the core,
wherein the at least one core or the at least one shell comprises a bulk semiconductor nanocrystal.

19. The method according to claim 15, wherein forming the colloidal dispersion corresponds to forming the colloidal dispersion by using one or more solvent diluted precursors.

20. The method according to claim 15, wherein the method further comprises the step of adding one or more ligands prior to and/or after forming the semiconductor film, thereby capping the bulk semiconductor nanocrystals or the bulk hetero nanocrystals with one or more ligands in the colloidal dispersion.

21. The method according to claim 20, wherein one or more of the ligands are dissolved in a solvent.

22. An optically-pumped or electrically-pumped device with feedback structure obtainable by the method as defined by claim 15.

23. An optically-pumped or electrically-pumped device with feedback structure comprising:
a substrate;
at least one optical confinement layer on top of the substrate, wherein one or more of the optical confinement layers comprise one or more integrated optical feedback structures; and
a semiconductor film on top of one or more of the optical confinement layers, or embedded within one of the optical confinement layers, or between the substrate and at least one of the optical confinement layers, or between at least two of the optical confinement layers,
wherein the semiconductor film comprises bulk semiconductor nanocrystals bulk semiconductor nanocrystals and/or bulk hetero nanocrystals, with a bulk hetero nanocrystal comprising at least two parts with one of these parts comprising a bulk semiconductor nanocrystal, with bulk semiconductor nanocrystals having a size in three independent directions larger than larger an upper limit for strong quantization of the corresponding bulk material, and with bulk semiconductor nanocrystals being defined as semiconductor nanocrystals having linear optical properties as determined by the corresponding bulk material composition, and not as determined by a size or diameter of the semiconductor nanocrystals because the semiconductor nanocrystals are not in a regime of quantum confinement and so demonstrate linear optical properties as determined by the corresponding bulk materials,
wherein the linear optical properties comprise absorption spectra and photoluminescence spectra, wherein the bulk semiconductor nanocrystals comprise:
one or more II-VI semiconductor materials or alloys thereof;
one or more III-V semiconductor materials or alloys thereof;
one or more IV-VI semiconductor materials or alloys thereof;
one or more Group IV semiconductor materials;
one or more Group I-III-VI₂ semiconductor materials or alloys thereof; or
any combinations thereof; and
wherein the one or more optical confinement layers are configured to confine one or more optical modes in the semiconductor film and to add an optical feedback function to the one or more optical modes.

24. The optically-pumped or electrically-pumped device with feedback structure according to claim 23, wherein the device is a laser or an Amplified Spontaneous Emission (ASE) source.

25. The optically-pumped or electrically-pumped device with feedback structure according to claim 23, wherein the semiconductor film comprises an intrinsic material gain larger than 2000 cm⁻¹.

26. The optically-pumped or electrically-pumped device with feedback structure according to claim 23, wherein an inverted state lifetime for the semiconductor film is equal to or larger than Ins.

27. The optically-pumped or electrically-pumped device with feedback structure according to claim 23, wherein a tuning range of the gain spectrum of the semiconductor film is equal to or smaller than 20% of the band gap energy.

28. The optically-pumped or electrically-pumped device with feedback structure according to claim 23, wherein a volume fraction of the bulk semiconductor nanocrystals and/or bulk hetero nanocrystals in the semiconductor film is larger than 0.5%.
